(19) United States
(12) Patent Application Publication
(10) Pub. No.: US 2021/0359004 A1
(43) Pub. Date: Nov. 18, 2021

(54) DISPLAY PANEL AND METHOD OF MANUFACTURING SAME

(71) Applicant: SHENZHEN CHINA STAR OPTOELECTRONICS SEMICONDUCTOR DISPLAY TECHNOLOGY CO., LTD., Shenzhen, Guangdong (CN)

(72) Inventor: Na AI, Shenzhen, Guangdong (CN)

(73) Assignee: SHENZHEN CHINA STAR OPTOELECTRONICS SEMICONDUCTOR DISPLAY TECHNOLOGY CO., LTD., Shenzhen, Guangdong (CN)

(21) Appl. No.: 16/620,110

(22) PCT Filed: Nov. 8, 2019
(86) PCT No.: PCT/CN2019/116725

§ 371 Date: Dec. 6, 2019

(30) Foreign Application Priority Data
Oct. 30, 2019 (CN) 201911041363.9

(51) Int. Cl. H01L 27/28; H01L 51/44; H01L 51/52; H01L 51/56

(52) U.S. Cl. CPC H01L 27/288; H01L 51/56; H01L 51/5237; H01L 51/448

(57) ABSTRACT

A display panel and a method of manufacturing the display panel are provided. The display panel includes a substrate, an organic electroluminescent diode device (OLED) disposed on the substrate, and an organic photodetector (OPD) disposed on the substrate. The organic photodetector and the organic electroluminescent diode device are disposed adjacent with each other.

### FIELD OF INVENTION

The present disclosure relates to the field of display technologies, and more particularly to a display panel and a method of manufacturing the same.

### BACKGROUND OF INVENTION

Current mobile devices such as smartphones and tablets are pursuing high screen ratios. However, electronic components such as an independent front fingerprint recognition, an independent distance sensor, and an independent front camera inevitably occupy space of a display panel.

Solutions typically involve cutting out a profiled screen with a notch or placing components underneath an active matrix organic light emitting diode (AMOLED) panel.

Combination of different types of organic devices is critical to uses of organic ultra-thin film devices to achieve a variety of electronic functions in smart wearable and medical systems.

Therefore, how to properly integrate organic electroluminescent diode devices (OLEDs) and organic photodetectors (OPDs) on a glass or a plastic substrate for use in pulse oximetry instruments and muscle contraction sensors aspects, etc. is a technical problem that needs to be solved urgently.

### SUMMARY OF INVENTION

An object of the present invention is to provide a display panel and a method of manufacturing the same, which solve issues of integrating an organic electroluminescent diode device (OLED) and an organic photodetector (OPD) into one body and utilize light emitted by sub-pixels of the organic electroluminescent diode device, such that automatic detection of sub-pixels of the organic photodetector is realized and a screen ratio is improved.

In order to solve the above issues, an embodiment of the present application provides a display panel. The display panel includes a substrate, an organic electroluminescent diode device disposed on the substrate, and an organic photodetector disposed on the substrate and disposed adjacent to the organic electroluminescent diode device.

In an embodiment of the present application, the organic electroluminescent diode device includes a blue sub-pixel, a red sub-pixel, and a green sub-pixel; the organic photodetector and the green sub-pixel are disposed in a same row or in a same column.

In an embodiment of the present application, the blue sub-pixel, the red sub-pixel, and the green sub-pixel each include a first electrode disposed on the substrate, a light emitting layer disposed on the first electrode, and a second electrode disposed on the light emitting layer.

In an embodiment of the present application, the blue sub-pixel, the red sub-pixel, and the green sub-pixel each further include a hole injection layer disposed on the first electrode, a hole transport layer disposed on the hole injection layer, the light emitting layer disposed on the hole transport layer, an electron transport layer disposed on the light emitting layer, an electron injection layer disposed on the electron transport layer, and the second electrode disposed on the electron injection layer.

In an embodiment of the present application, the organic photodetector includes a first electrode disposed on the substrate, an organic semiconductor functional layer disposed on the first electrode, and a second electrode disposed on the organic semiconductor functional layer.

In an embodiment of the present application, the display panel further includes a passivation layer disposed on the organic electroluminescent diode device and the organic photodetector.

An embodiment of the present application further provides a method of manufacturing a display panel including steps of: providing a substrate, forming an organic electroluminescent diode device on the substrate, forming an organic photodetector on the substrate, and the organic photodetector being disposed adjacent to the organic electroluminescent diode device.

In an embodiment of the present application, forming the organic electroluminescent diode device includes steps of: forming a blue sub-pixel, a red sub-pixel, and a green sub-pixel on the substrate, wherein forming the blue sub-pixel, the red sub-pixel, and the green sub-pixel further includes sequentially depositing a first electrode, a hole injection layer, a hole transport layer, a light emitting layer, an electrode transport layer, an electron injection layer, and a second electrode by vacuum evaporation, spin coating, or inkjet printing, and wherein the organic photodetector and the green subpixel are disposed in a same row or in a same column.

In an embodiment of the present application, forming the organic photodetector includes steps of: forming a first electrode on the substrate by vacuum evaporation, spin coating, or inkjet printing, forming an organic semiconductor functional layer on the first electrode by vacuum evaporation, spin coating, or inkjet printing, and forming a second electrode on the organic semiconductor functional layer by vacuum evaporation, spin coating, or ink jet printing.

In an embodiment of the present application, after forming the organic electroluminescent diode device and the organic photodetector, the method further includes steps of: forming a passivation layer on the organic electroluminescent diode device and the organic photodetector.

Beneficial effects of the present application are that: a display panel and a method of manufacturing the same are provided to realize integration of an organic electroluminescent diode device (OLED) and an organic photodetector (OPD) and reach automatic detection of sub-pixels of the organic photodetector by using light emitted from sub-pixels (RGB) of the organic electroluminescent diode device. Thereby, a screen ratio is increased and can be applied to fingerprints, heart rate, blood oxygen, distance sensing, and the like.

### DESCRIPTION OF DRAWINGS

FIG. 1 is a schematic plan view showing a planar structure of a pixel unit of a display panel according to a first embodiment of the present invention.

FIG. 2 is a schematic cross-sectional view showing a display panel according to a first embodiment of the present invention.

FIG. 3 is a flowchart of a method of manufacturing a display panel according to a first embodiment of the present invention.

FIG. 4 is a flowchart showing steps of forming an organic photodetector in FIG. 3.

FIG. 5 is a schematic plan view showing a planar structure of a pixel unit of a display panel according to a second embodiment of the present invention.

FIG. 6 is a flowchart of a method of manufacturing a display panel according to a second embodiment of the present invention.

Parts in the figure are identified as follows:

10 substrate, 20 organic electroluminescent diode device, 30 organic photodetector

21 first electrode, 22 hole injection layer, 23 hole transport layer, 24 light emitting layer

25 electron transport layer, 26 electron injection layer, 27 second electrode

31 organic semiconductor functional layer, 100 display panel, 101 pixel unit

201 blue sub-pixel, 202 red sub-pixel, 203 green sub-pixel

301 photodetection pixel

### DETAILED DESCRIPTION OF PREFERRED EMBODIMENTS

The following description of the various embodiments is provided to illustrate the specific embodiments of the present invention. The directional terms mentioned in the present invention, such as up, down, front, back, left, right, inside, outside, side, etc., are merely directions referring to the drawings. Therefore, the directional terminology used is for the purpose of illustration and understanding of the present invention and is not intended to limit the present invention. In the figures, structurally similar elements are denoted by the same reference numerals.

### Embodiment 1

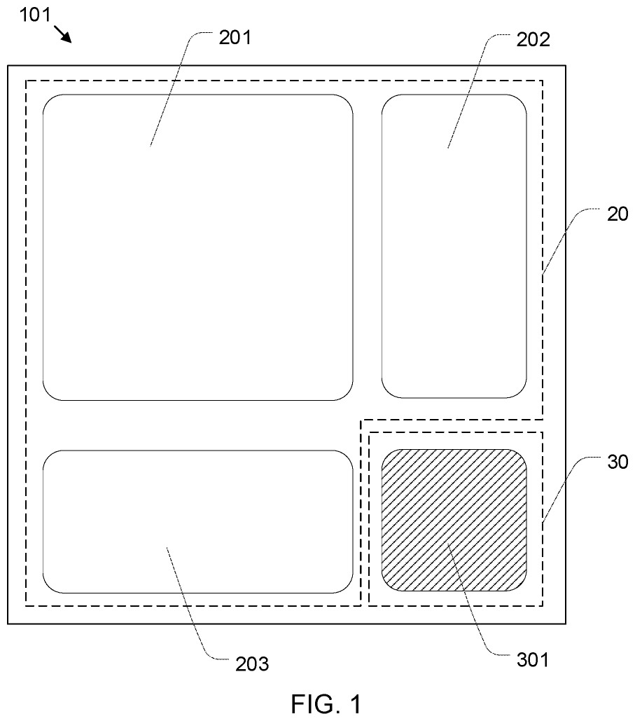

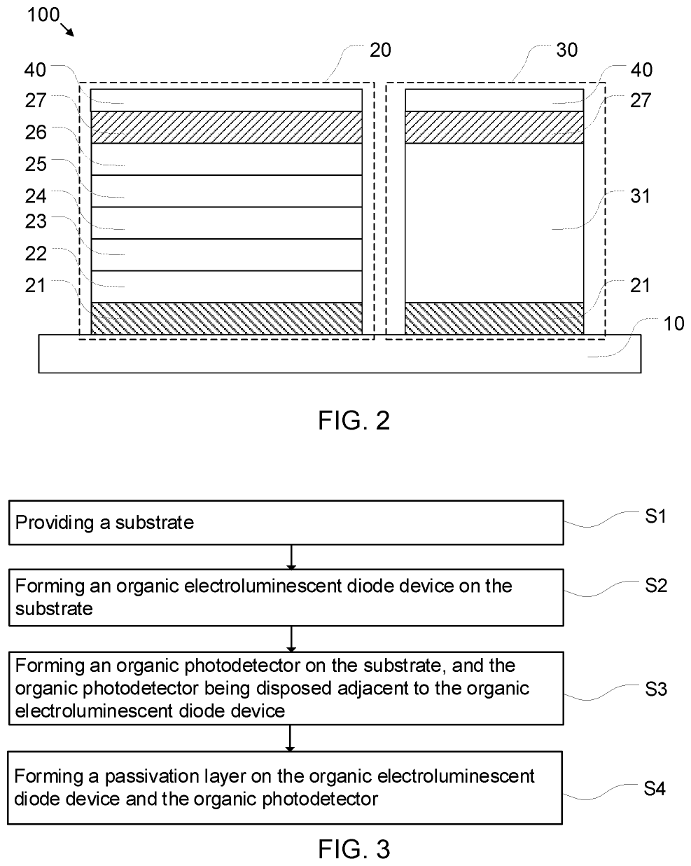

Referring to FIG. 1 and FIG. 2, a first embodiment of the present invention provides a display panel 100 including a substrate 10, an organic electroluminescent diode device 20 disposed on the substrate 10, and an organic photodetector 30 disposed on the substrate 10. The organic photodetector 30 is disposed adjacent to the organic electroluminescent diode device 20.

Material of the substrate 10 includes glass, plastic, or a flexible substrate material. The flexible substrate material includes a combination of one or more of polyimide (PI), polyethersulfone (PES), polyacrylate (PAR), polyetherimide (PEI), polyethylene naphthalate (PEN), polyethylene terephthalate (PET), polyphenylene sulfide (PPS), polyallylate, polycarbonate (PC), cellulose triacetate (TAC), cellulose acetate propionate (CAP), or acrylamide. Because the polyimide is one of organic polymers having the best overall performance, flexible material has good optical, chemical resistance, and water and oxygen barrier properties. Therefore, the flexible substrate material in the embodiment is preferably a polyimide material.

As shown in FIG. 1, the organic photodetector 30 of the display panel 100 and the organic electroluminescent diode device 20 are interleaved and integrated with each other. In this embodiment, the organic electroluminescent diode device 20 includes a blue sub-pixel 201, a red sub-pixel 202, and a green sub-pixel 203. In FIG. 1, a photodetection pixel 301 of the organic photodetector 30 is disposed in a same row as the green sub-pixel 203 and is disposed in a same column as the red sub-pixel 202. The blue sub-pixel 201, the red sub-pixel 202, the green sub-pixel 203, and the photodetection pixel 301 collectively form a pixel unit 101.

As shown in FIG. 2, in the embodiment, the blue sub-pixel 201, the red sub-pixel 202, and the green sub-pixel 203 each include a first electrode 21, a light emitting layer 24, and a second electrode 27 stacked in an order from bottom to top. The first electrode 21 is disposed on the substrate 10, the light emitting layer 24 is disposed on the first electrode 21, and the second electrode 27 is disposed on the light emitting layer 24.

As shown in FIG. 2, in the embodiment, the blue sub-pixel 201, the red sub-pixel 202, and the green sub-pixel 203 further include a hole injection layer 22, a hole transport layer 23, an electron transport layer 25, and an electron injection layer 26. Specifically, the hole injection layer 22 is disposed on the first electrode 21, the hole transport layer 23 is disposed on the hole injection layer 22, the light emitting layer 24 is disposed on the hole transport layer 23, the electron transport layer 25 is disposed on the light emitting layer 24, the electron injection layer 26 is disposed on the electron transport layer 25, and the second electrode 27 is disposed on the electron injection layer 26.

The first electrode 21, the hole injection layer 22, the hole transport layer 23, the light emitting layer 24, the electron transport layer 25, the electron injection layer 26, and the second electrode 27 have a thickness ranging from 10 nm to 200 nm.

As shown in FIG. 2, in the embodiment, the organic photodetector 30 includes the first electrode 21, an organic semiconductor functional layer 31, and the second electrode 27. In particular, the first electrode 21 is disposed on the substrate 10. The organic semiconductor functional layer 31 is disposed on the first electrode 21, and the second electrode 27 is disposed on the organic semiconductor functional layer 31. The first electrode 21, the organic semiconductor functional layer 31, and the second electrode 27 are formed by vacuum evaporation, spin coating, or inkjet printing.

As shown in FIG. 2, in the embodiment, a passivation layer 40 is further disposed on the organic electroluminescent diode device 20 and the organic photodetector 30. It can be understood that the passivation layer is specifically disposed on the second electrode 27 to function to block water and oxygen.

Referring to FIG. 3 again, an embodiment of the present invention further provides a method of manufacturing the display panel 100, including steps of:

Step S1, providing a substrate 10. Material of the substrate 10 includes glass, plastic, or a flexible substrate material.

Step S2, forming an organic electroluminescent diode device 20 on the substrate 10.

Step S3, forming an organic photodetector 30 on the substrate 10, and the organic photodetector 30 being disposed adjacent to the organic electroluminescent diode device 20.

In the embodiment, the step S2 of forming the organic electroluminescent diode device 20 includes following steps.

A blue sub-pixel 201, a red sub-pixel 202, and a green sub-pixel 203 are formed on the substrate 10. The forming the blue sub-pixel 201, the red sub-pixel 202, and the green sub-pixel 203 specifically includes sequentially depositing the first electrode 21, the hole injection layer 22, the hole transport layer 23, the light emitting layer 24, the electron transport layer 25, the electron injection layer 26, and the second electrode 27 by vacuum evaporation, spin coating, or inkjet printing. The first electrode 21, the hole injection layer 22, the hole transport layer 23, the light emitting layer 24, the electron transport layer 25, the electron injection layer 26, and the second electrode 27 have a thickness ranging from 10 nm to 200 nm. The organic photodetector 30 and the green sub-pixel 203 are disposed in a same row or in a same column.

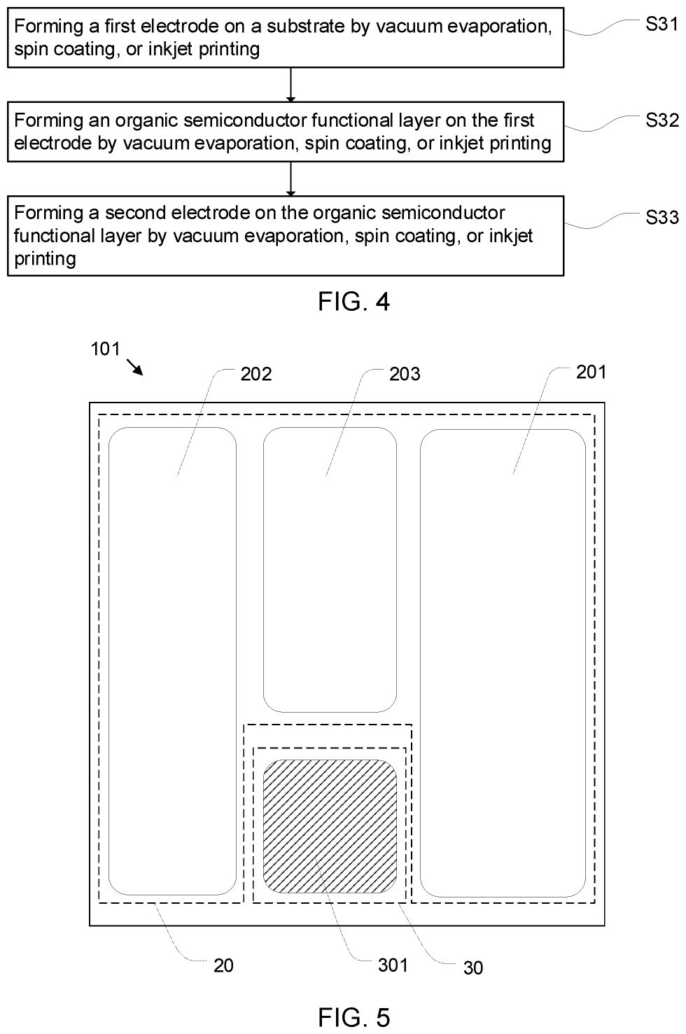

Referring to FIG. 4 again, in the embodiment, the step S3 of forming the organic photodetector 30 includes following steps of:

Step S31, forming a first electrode 21 on a substrate 10 by vacuum evaporation, spin coating, or inkjet printing.

Step S32, forming an organic semiconductor functional layer 31 on the first electrode 21 by vacuum evaporation, spin coating, or inkjet printing.

Step S33, forming a second electrode 27 on the organic semiconductor functional layer 31 by vacuum evaporation, spin coating, or inkjet printing.

In the embodiment, after the step S2 of forming the organic electroluminescent diode device 20 and the step S3 of the organic photodetector 30, the method further includes steps of:

Step S4, forming a passivation layer on the organic electroluminescent diode device 20 and the organic photodetector 30.

It can be understood that the passivation layer is specifically disposed on the second electrode 27 to function to block water and oxygen.

### Embodiment 2

Referring to FIG. 5, most of the technical features in the first embodiment are included in the second embodiment, except that the photodetection pixel 301 of the organic photodetector 30 and the green sub-pixels 203 are disposed in a same column in the second embodiment, instead of the photodetection pixels 301 of the organic photodetector 30 and the green sub-pixel 203 being disposed in the same row in the first embodiment.

It can be seen that in the first embodiment of FIG. 1 and the second embodiment of FIG. 5, the organic photodetector 30 and the green sub-pixel 203 are disposed in the same row or in the same column.

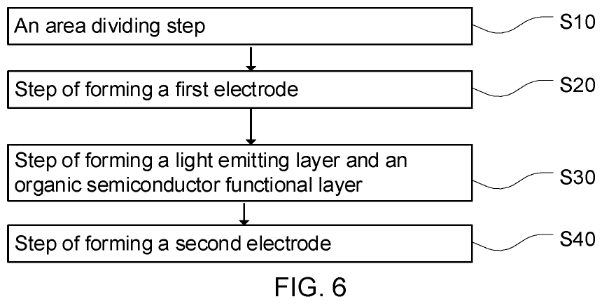

It can be understood that the order of the steps in the manufacturing method of the display panel 100 may not be strictly limited. Referring to FIG. 6, in the second embodiment, forming the organic electroluminescent diode device 20 and the organic photodetector 30 on the substrate 10 may also include steps of:

Step S10, an area dividing step, forming the blue sub-pixel 201, the red sub-pixel 202, and the green sub-pixel 203 on the substrate 10, wherein the organic photodetector 30 and the green sub-pixel 203 are disposed in the same row or in the same column.

Step S20, step of forming a first electrode 21, forming the first electrode 21 on the substrate 10 by vacuum evaporation, spin coating, or inkjet printing, wherein the first electrode 21 is located in an area wherein the blue sub-pixel 201, the red sub-pixel 202, the green sub-pixel 203, the organic photodetector 30 are located.

Step S30, step of forming a light emitting layer 24 and an organic semiconductor functional layer 31, forming the light emitting layer 24 and the organic semiconductor functional layer 31 on the first electrode 21 by vacuum evaporation, spin coating, or inkjet printing, wherein the light emitting layer 24 is located in an area where the blue sub-pixel 201, the red sub-pixel 202, and the green sub-pixel 203 are located, and the organic semiconductor functional layer 31 is located in an area where the organic photodetector 30 is located.

Step S40, step of forming a second electrode 27, forming the second electrode 27 on the light emitting layer 24 and the organic semiconductor functional layer 31 by vacuum evaporation, spin coating, or inkjet printing.

The first electrode 21, the light emitting layer 24, and the second electrode 27 form the organic electroluminescent diode device 20. The first electrode 21, the organic semiconductor functional layer 31, and the second electrode 27 forms the organic photodetector 30.

Specifically, in the step S30, before the step of forming the light emitting layer 24, the hole injection layer 22 and the hole transport layer 23 are sequentially deposited on the first electrode 21 at positions of the blue sub-pixel 201, the red sub-pixel 202, and the green sub-pixel 203 by vacuum evaporation. spin coating, or ink jet printing. After the step of forming the light emitting layer 24, the electron transport layer 25 and the electron injection layer 26 are sequentially deposited on the light emitting layer 24 by vacuum evaporation, spin coating, or ink jet printing.

The first electrode 21, the hole injection layer 22, the hole transport layer 23, the light emitting layer 24, the electron transport layer 25, the electron injection layer 26, and the second electrode 27 have a thickness ranging from 10 nm to 200 nm.

It can be seen that the expressions in the above two embodiments are different descriptions of manufacturing steps of the manufacturing method of the display panel 100. As long as the combination of the various manufacturing steps of the display panel 100 can be completed, it is within the scope of the present invention.

Technical effects of the present application are that: a display panel and a method of manufacturing the same are provided to realize integration of an organic electroluminescent diode device (OLED) and an organic photodetector (OPD) and reach automatic detection of sub-pixels of the organic photodetector by using light emitted from sub-pixels (RGB) of the organic electroluminescent diode device. Thereby, a screen ratio is increased and can be applied to fingerprints, heart rate, blood oxygen, distance sensing, and the like.

The above is only a preferred embodiment of the present invention. It should be noted that many modifications and refinements can be made by those skilled in the art without departing from the principles of the present invention. These modifications and refinements should also be considered as the protection scope of the present invention.

What is claimed is:

1. A display panel, comprising:
a substrate;
an organic electroluminescent diode device disposed on the substrate; and
an organic photodetector disposed on the substrate and disposed adjacent to the organic electroluminescent diode device.

2. The display panel according to claim 1, wherein the organic electroluminescent diode device comprises a blue sub-pixel, a red sub-pixel, and a green sub-pixel; the organic photodetector and the green sub-pixel are disposed in a same row or in a same column.

3. The display panel according to claim 2, wherein the blue sub-pixel, the red sub-pixel, and the green sub-pixel each comprise:
a first electrode disposed on the substrate;
a light emitting layer disposed on the first electrode; and
a second electrode disposed on the light emitting layer.

4. The display panel according to claim 3, wherein the blue sub-pixel, the red sub-pixel, and the green sub-pixel each further comprise:
a hole injection layer disposed on the first electrode;
a hole transport layer disposed on the hole injection layer;
the light emitting layer disposed on the hole transport layer;
an electron transport layer disposed on the light emitting layer;
an electron injection layer disposed on the electron transport layer; and
the second electrode disposed on the electron injection layer.

5. The display panel according to claim 1, wherein the organic photodetector comprises:
a first electrode disposed on the substrate;
an organic semiconductor functional layer disposed on the first electrode; and
a second electrode disposed on the organic semiconductor functional layer.

6. The display panel according to claim 1, further comprising a passivation layer disposed on the organic electroluminescent diode device and the organic photodetector.

7. A method of manufacturing a display panel, comprising steps of:
providing a substrate;
forming an organic electroluminescent diode device on the substrate; and
forming an organic photodetector on the substrate, and the organic photodetector being disposed adjacent to the organic electroluminescent diode device.

8. The method of manufacturing the display panel according to claim 7, wherein forming the organic electroluminescent diode device comprises steps of:
forming a blue sub-pixel, a red sub-pixel, and a green sub-pixel on the substrate;
wherein forming the blue sub-pixel, the red sub-pixel, and the green sub-pixel further comprises sequentially depositing a first electrode, a hole injection layer, a hole transport layer, a light emitting layer, an electrode transport layer, an electron injection layer, and a second electrode by vacuum evaporation, spin coating, or inkjet printing; and
wherein the organic photodetector and the green subpixel are disposed in a same row or in a same column.

9. The method of manufacturing the display panel according to claim 7, wherein forming the organic photodetector comprises steps of:
forming a first electrode on the substrate by vacuum evaporation, spin coating, or inkjet printing;
forming an organic semiconductor functional layer on the first electrode by vacuum evaporation, spin coating, or inkjet printing; and
forming a second electrode on the organic semiconductor functional layer by vacuum evaporation, spin coating, or ink jet printing.

10. The method of manufacturing the display panel according to claim 7, wherein after forming the organic electroluminescent diode device and the organic photodetector, the method further comprises steps of:
forming a passivation layer on the organic electroluminescent diode device and the organic photodetector.
